(19) United States
(12) Patent Application Publication
(10) Pub. No.: US 2015/0262970 A1
(43) Pub. Date: Sep. 17, 2015

(54) SEMICONDUCTOR MEMORY DEVICE MANUFACTURING METHOD AND SEMICONDUCTOR MEMORY DEVICE

(71) Applicant: KABUSHIKI KAISHA TOSHIBA, Tokyo (JP)

(72) Inventor: Saku HASHIURA, Yokkaichi Mie (JP)

(21) Appl. No.: 14/573,465

(22) Filed: Dec. 17, 2014

Related U.S. Application Data
(60) Provisional application No. 61/952,504, filed on Mar. 13, 2014.

(51) Int. Cl. H01L 23/00; G11C 5/14; H01L 29/32; H01L 27/115

(52) U.S. Cl. CPC H01L 24/85; H01L 24/49; H01L 27/115; G11C 5/147; H01L 29/32

(57) ABSTRACT

According to an embodiment, a semiconductor memory device includes a semiconductor chip that includes first memory regions and second memory regions provided with a memory cell for storing data, and a packaging substrate in which a bonding wire is bonded to the semiconductor chip by bonding wire, in which a concentration of a chemical element of a mobile ion in the first memory region is higher than a concentration of a chemical element of a mobile ion in the second memory region.

### CROSS-REFERENCE TO RELATED APPLICATION

This application is based upon and claims the benefit of priority from U.S. Provisional Patent Application No. 61/952,504, filed Mar. 13, 2014, the entire contents of which are incorporated herein by reference.

### FIELD

Embodiments described herein relate to a semiconductor memory device manufacturing method and a semiconductor memory device.

### BACKGROUND

In a semiconductor memory device (a semiconductor chip), an internal component such as a memory cell, a transistor for driving a memory cell, a resistor, a capacitance, various wirings, and an interlayer insulating film is formed on a substrate by using various materials. When the component is formed, various gases are used in addition to the various materials (for example, copper (Cu) or the like).

Subsequently, the semiconductor memory device is packaged and shipped. In the packaging procedure, when a thermal stress is applied such as heat applied to cause solder to reflow during the wire bonding process, a chemical element included in the various materials or/and various gases described above becomes a mobile ion which can migrate into an active area of the device, and thus data of the memory cell may be changed.

### BRIEF DESCRIPTION OF THE DRAWINGS

FIG. 1A is an example of a schematic circuit diagram illustrating an electrical configuration of a portion of a semiconductor memory device according to a first embodiment.

FIG. 1B is an example of a plan view schematically illustrating the location of electrical elements in an inner portion of a memory cell array according to the first embodiment.

FIG. 1C is an example of a plan view schematically illustrating a mounting example of a semiconductor chip according to the first embodiment.

FIG. 1D is an example schematically illustrating a threshold voltage distribution of the memory cell according to the first embodiment.

FIG. 2 is an example of a plan view schematically illustrating a structure of a portion of the semiconductor memory device according to the first embodiment.

FIG. 3A is an example of a longitudinal sectional side view schematically illustrating a structural example of a cell unit according to the first embodiment.

FIG. 3B is an example of a longitudinal sectional side view schematically illustrating a diffusion of a mobile ion in a block of the memory cell array according to the first embodiment.

FIG. 4A and FIG. 4B are an example of a characteristic diagram schematically illustrating a temperature characteristic of a diffusion coefficient according to the first embodiment.

FIG. 5 is an example of a plan view schematically illustrating the diffusion image of the mobile ion from an adjacent block according to the first embodiment.

FIG. 6 is an example illustrating reflow time dependency of a threshold voltage degraded amount according to the first embodiment.

FIG. 7 is an example of a flowchart schematically illustrating a manufacturing procedure example according to the first embodiment.

FIG. 8 is an example of a region in which a captured amount of the mobile ion in the memory cell array is larger than other regions according to the first embodiment.

FIG. 9 is an example of a region in which a captured amount of a mobile ion in a memory cell array is larger than other regions according to a second embodiment.

FIG. 10 is an example of a region in which a captured amount of a mobile ion in a memory cell array is larger than other regions according to a third embodiment.

FIG. 11 is an example of the region in which the captured amount of the mobile ion in the memory cell array is larger than the other regions according to the third embodiment.

FIG. 12 is an example of a flowchart schematically illustrating a manufacturing procedure example according to a fourth embodiment.

### DESCRIPTION

According to an embodiment, a semiconductor memory device manufacturing method for mounting a semiconductor chip in which memory cells are provided on a packaging substrate includes selecting a target cell from among the memory cells in the memory device, setting the voltage of the memory cells to a first voltage and the voltage of the target cell to a second voltage, greater than the first voltage, performing wire bonding to attach wires between the semiconductor chip and the packaging substrate at a first temperature which is higher than a normal operating temperature of the semiconductor memory device after the voltage of the target cell is set to the second voltage, and setting the second voltage of the target cell to a third voltage which is lower than the second voltage by reducing the second voltage after the semiconductor chip is wire bonded to the packaging substrate.

According to another embodiment, a semiconductor memory device includes a semiconductor chip that includes a memory area including first memory regions and second memory regions for storing data provided within a memory cell, and a packaging substrate including a bonding wire which is bonded to the semiconductor chip by wire bonding at a first time and temperature. A concentration of a chemical element of a mobile ion in the first memory region is higher than a concentration of a chemical element of a mobile ion in the second memory region.

Hereinafter, an embodiment applied to a NAND-type flash memory device as a semiconductor memory device will be described with reference to the drawings. Furthermore, the drawings are schematic, and the relationship between a thickness and a planar dimension, a ratio of the thickness of each layer, or the like may not be coincident with that of an actual device. In addition, directions of up, down, right, and left also illustrate a relative direction when a circuit forming surface side of a semiconductor substrate (described later) is an up direction, and may not be coincident with a direction based on the direction of gravitational acceleration.

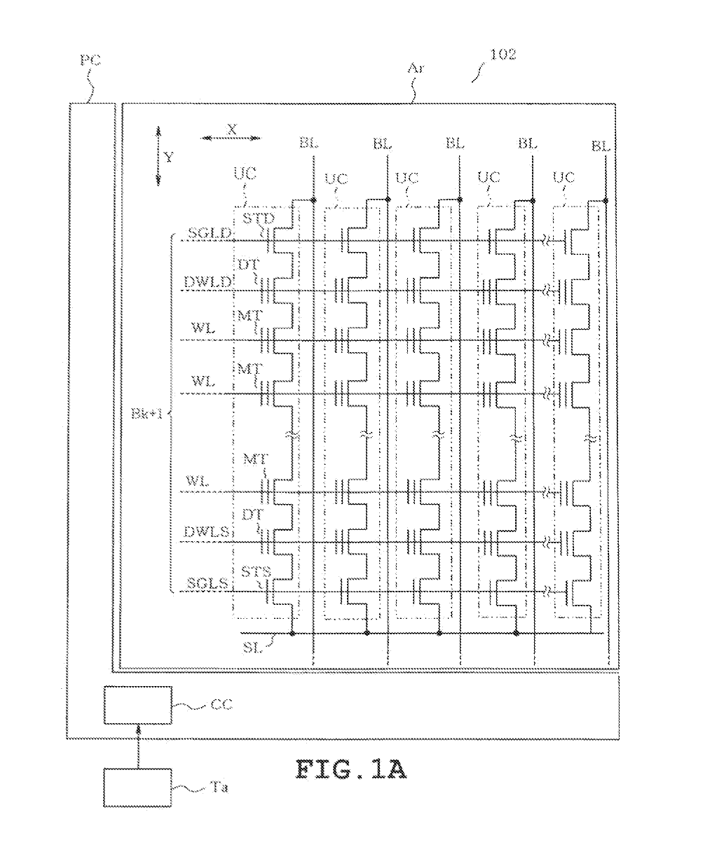

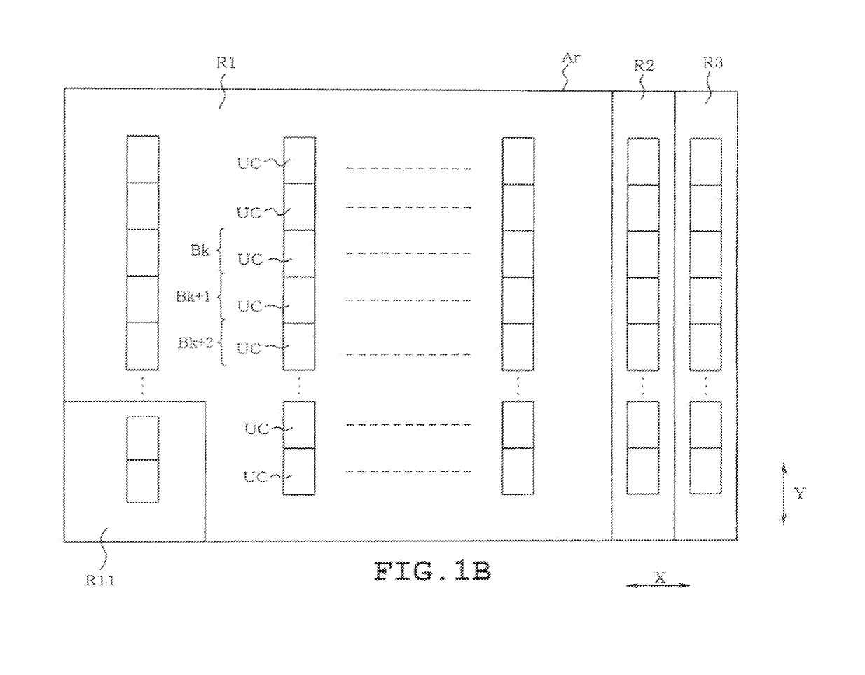

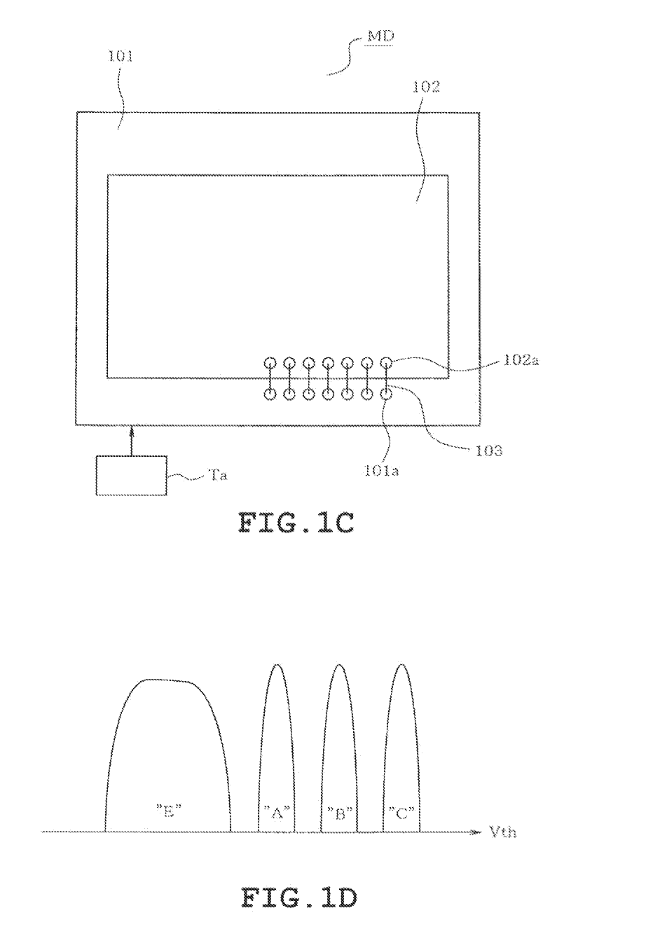

FIG. 1A is an example schematically illustrating an electrical configuration example of a semiconductor memory device MD. In addition, FIG. 1B is an example schematically illustrating positional relationships of cell units or the like within a portion of a memory cell array. FIG. 1C is an example schematically illustrating amounting example of a semiconductor chip on a packaging substrate 101.

As illustrated in FIG. 1C, a semiconductor memory device MD is configured by mounting a semiconductor chip 102 on a packaging substrate 101. Bonding pads 101a are formed on the packaging substrate 101, and bonding pads 102a are formed on the semiconductor chip 102. Between the respective bonding pads 101a and 102a, bonding wires 103 are connected. The bonding wires 103 comprise, for example, copper (Cu) wires. The semiconductor memory device MD may undergo a performance test by being connected to an external test apparatus Ta.

As illustrated in FIG. 1A, the semiconductor chip 102 of the semiconductor memory device MD includes a memory cell array Ar in which a plurality of memory cells MT are disposed in a planar matrix, and a peripheral circuit PC. The peripheral circuit PC includes a control circuit CC for performing reading, writing, and erasing of each memory cell MT of the memory cell array Ar. When a test command from the test apparatus Ta is received, a product test may be performed with respect to each portion in the semiconductor chip 102 using the control circuit CC.

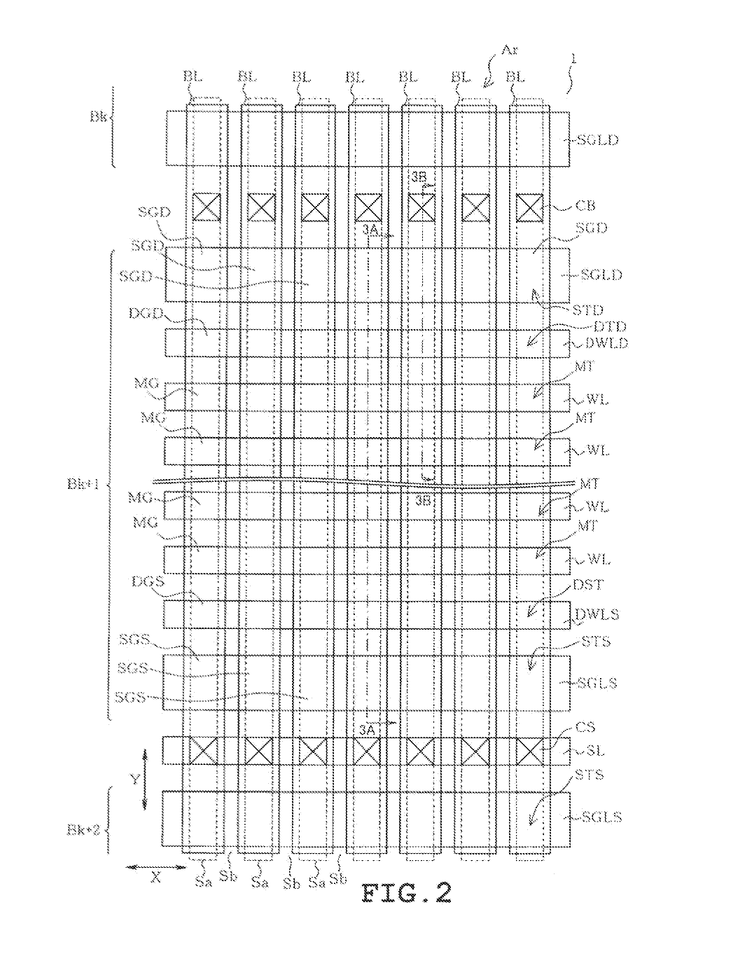

The memory cell array Ar includes a plurality of blocks (Bk, Bk+1, Bk+2 . . . : k≧1) (refer to FIG. 2). Since the plurality of blocks (Bk, Bk+1, Bk+2 . . . ) include the same circuit configuration as each other, for convenience of description, only one block Bk+1 is illustrated in FIG. 1A. The block Bk+1 includes a plurality of cell units UC.

As illustrated in FIG. 1A, each cell unit UC of a block (Bk=1) includes bit line side selector transistors STD which are each individually connected to one of a plurality of bit lines BL, source side selector transistors STS which are all connected to a common source line SL, and, for example, 64 memory cell transistors (hereinafter, simply referred to as a memory cell) MT which are directly series (source to drain or drain to source) connected between the plurality of selector transistors STD-STS.

In addition, between the selector transistor STD and the memory cell MT, a dummy cell DTD is connected. In addition, between the selected transistor STS and the memory cell MT, a dummy cell DTS is connected. The number of dummy cells DTD and DTS is not limited to one, but a plurality of dummy cells may be provided between the selector transistors STD and STS. The plurality of memory cells MT disposed between the selected transistors STD-STS configure a cell string.

In FIG. 1A, gates of adjacent memory cells MT disposed in a word line direction (an X direction) across adjacent cell units UC are commonly connected to a word line WL. In addition, in FIG. 1A, the gates of adjacent selector transistors STD disposed in the word line direction across adjacent cell units UC are commonly connected to a selector gate line SGLD. Furthermore, in FIG. 1A, the gates of adjacent selector transistors STS disposed in the word line direction across cell units UC are commonly connected to a selector gate line SGLS. Furthermore, the adjacent dummy cells DTD disposed in the word line direction across cell units UC are commonly connected to a dummy word line DWLD. Furthermore, the adjacent dummy cells DTS disposed in the word line direction are commonly connected to a dummy word line DWLS.

Each of the individual bit lines BL is connected to a drain of a single selector transistor STD of a cell unit UC. The bit line BL extends in the bit line direction (a Y direction) in FIG. 1A. In addition, for example, the sources of the selector transistor STS of a block are commonly connected to a source line SL. The source line SL extends in the word line direction (the X direction) in FIG. 1A.

As illustrated in FIG. 1B, the memory cell array Ar includes a user area R1 which is a region usable by a user, i.e., where data can be written, read, and erased, a Read Only Memory (ROM) area R2, and a dummy area R3. The user area R1 is allocated as the region usable by the user. For example, when the user stores the data of a picture, the data is stored in the memory cells disposed in the user area R1. The user area R1 may include the memory cell MT of a so-called Multi Level Cell (MLC). As illustrated in FIG. 1D, the original threshold voltage of each memory cell MT may be set such that the threshold voltage thereof includes a plurality of threshold voltage distributions “E”, “A”, “B”, and “C”, the number of which is more than or equal to 3. As a result, the memory cells MT in the user area R1 may maintain data of the plurality of bits, respectively.

The ROM area R2 is allocated as a region unusable by the user, and includes the memory cells MT in which the parameters required for operation of the semiconductor memory device MD are written immediately before a shipment of the semiconductor memory device MD. The ROM area R2 may include the cell units UC provided with memory cells MT of a so-called Single Level Cell (SLC). The memory cells MT of the SLC are memory cells which store information using the difference between the two lower threshold voltages among the 3 or more threshold voltage distributions, and each of the memory cells MT in the ROM area R2 may maintain data related to a single bit.

Since a plurality of semiconductor chips 102 are formed on a semiconductor wafer, the threshold voltage and other characteristics of each of the number of semiconductor chips from a single wafer, or from different wafers, may be different from each other. For this reason, a write voltage, a read voltage, an erase voltage, and the like for an operation in a memory cell MT may be different between each of the semiconductor chips 102. Therefore, the ROM area R2 of the semiconductor memory device MD maintains the voltage information or the like of the different memory cells as an operational parameter, and thus memory performance with high reliability is preserved.

The dummy area R3 is allocated in this embodiment as a region unusable by the user, and is a region disposed for preferentially attracting mobile ions 50 (for example, a copper ion (Cu⁺), a sodium ion (Na⁺), a hydroxide ion (OH⁻), an oxonium ion (H₃O⁺), or the like) (described later). In this embodiment, the dummy area R3 is disposed separately from the user area R1 and the ROM area R2, although the dummy area R3 may not be disposed in a region separated from the areas R1 and R2 and the dummy area R3 may be disposed in a portion of the areas R1 and R2.

As illustrated in FIG. 1B, the user area R1 is located, for example, at one end portion in the X direction of the memory cell array Ar, and the dummy area R3 is located, for example, at the other end portion in the X direction of the memory cell array Ar. The ROM area R2 is disposed, for example, between the areas R1 and R3. In the user area R1, the cell units UC are disposed in parallel in the X direction and the Y direction.

FIG. 2 is a schematic plan view of an example illustrating a layout pattern of a portion of the memory cell region. As illustrated in FIG. 2, in the memory cell array Ar, a component separation region Sb of a STI structure extends along the Y direction of the semiconductor substrate 1. The semiconductor substrate 1 is configured on, for example, a p-type monocrystalline silicon substrate. A plurality of component separation regions Sb are formed in the X direction at a predetermined interval, and thus a plurality of component regions Sa therebetween are separated (spaced) in the X direction.

In addition, the selector gate line SGLD contacts the gates of the selector transistors STD, and extends along the word line direction (the X direction). The selector gate lines SGLD of two blocks Bk and Bk+1 adjacent in the Y direction interpose therebetween in the Y direction the location of the bit line contact electrodes CB as shown in FIG. 2. The bit line contact electrodes CB are formed on the component regions Sa extending between an adjacent pair of selector gate lines SGLD, respectively.

In addition, the selected gate lines SGLS contacts the gates of the selector transistors STS, and extends along the word line direction (the X direction). The selector gate lines SGLS of two adjacent blocks Bk+1 and Bk+2 adjacent in the Y direction interpose therebetween in the Y direction the location of the source line contact electrodes CS as shown in FIG. 2. The source line contact electrodes CS are formed on the component regions Sa where they extend between an adjacent pair of selector gate lines SGLS, respectively, and a source line SL is configured across the source line contact electrode CS. In addition, the dummy word line DWLD contact the dummy cells DTD, and extends along the word line direction (the X direction). In addition, the dummy word line DWLS contacts the dummy cells DTS, and extends along the word line direction (the X direction).

In the plan view of a portion of the memory cell array Ar illustrated in FIG. 2, the gates MG of the memory cells MT are formed where the component regions Sa intersect the word lines WL. In addition, the selector gate SGD of the selector transistor STD is formed on the component regions Sa where they intersect with the selector gate lines SGLD. In addition, the selector gates SGS of the selector transistors STS are formed on the component regions Sa where they intersect with the selector gate line SGLS.

In addition, the selector gates DGD of the dummy cells DTD are formed on the component regions Sa where they intersect with the dummy word line DWLD. In addition, the selector gates DGS of the dummy cells DTS are formed on the component regions Sa where they intersect with the dummy word line DWLS. Furthermore, in the peripheral circuit PC, various transistors for driving the memory cell MT such as a high-voltage transistor or a low-voltage transistor are formed, but they are not illustrated.

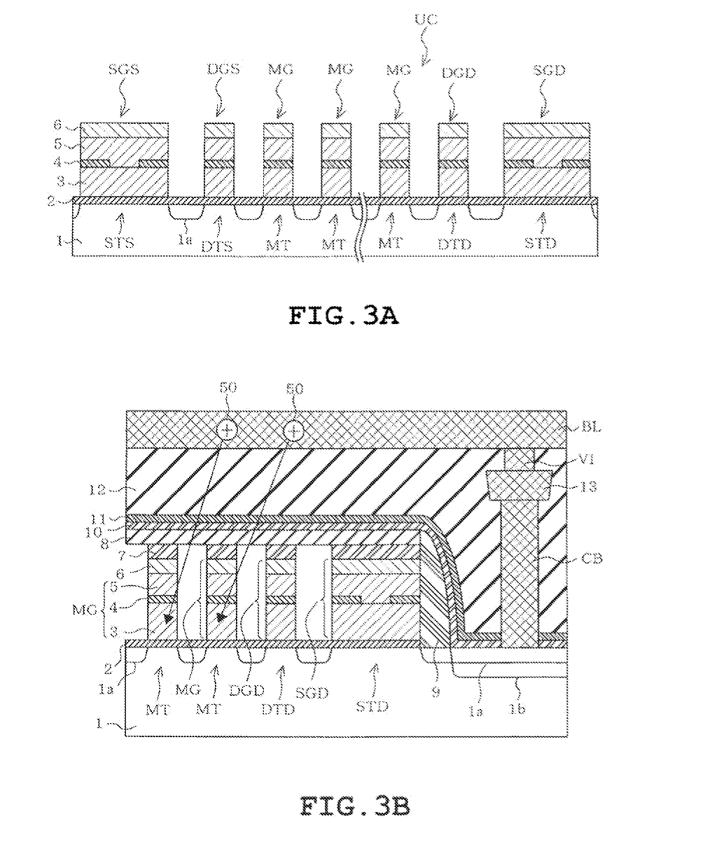

FIG. 3A is a longitudinal sectional side view schematically illustrating the cross-sectional structure of one cell unit UC. As illustrated in FIG. 3A, a tunnel insulating film 2 is formed on the semiconductor substrate 1. On the tunnel insulating film 2, the selector gates SGS and SGD, the dummy gates DGD and DGS, and the memory cell gates MG are disposed side by side. The dummy gate DGS is disposed on the selector gate SGS side of the cell unit UC, and the dummy gate DGD is disposed on the selector gate SGD side of the cell unit UC. Furthermore, the gates MG of the plurality of memory cells MT are disposed between the dummy gates DGS-DGD.

The gates MG of the memory cells MT are configured by stacking a charge storage layer 3, an inter-electrode insulating film 4, a polysilicon film 5, and a metallic film 6 on the tunnel insulating film 2. The polysilicon film 5 and the metallic film 6 configure a control electrode.

The tunnel insulating film 2 is formed, for example, of a silicon dioxide film. The charge storage layer 3 is configured, for example, of polysilicon in which an n-type dopant (for example, phosphorus (p) or arsenic (As)) is provided such as by ion implanting or diffusing the dopant therein. The charge storage layer 3 may include a film such as a silicon nitride film which functions as a charge trap. The inter-electrode insulating film 4 includes, for example, a high-dielectric insulating film (High-k film) such as alumina or hafnium oxide, instead of a nitride film such as an Oxide-Nitride-Oxide (ONO) film, a Nitride-Oxide-Nitride-Oxide-Nitride (NONON) film, or an intermediate film of the ONO film or the NONON film described above.

In addition, the structure of the dummy gates DGD and DGS is identical to the structure of the gates MG. In addition, the structure of the selector gates SGD and SGS is substantially identical to the structure of the gate MG, except an opening is provided in the inter-electrode insulating film 4 of the selector gates SGD and SGS, and thus the charge storage layer 3 and the polysilicon film 5 come in contact with each other.

FIG. 3B is an example of a longitudinal sectional side view schematically illustrating an upper layer wiring structure of the cell unit on the selected gate SGD side of the memory cell array Ar. As illustrated in FIG. 3B, a first insulating film 7 is formed on each metallic film 6 of the gate MG, the selected gate SGD, and the dummy gate DGD. The first insulating film 7 is formed, for example, of a silicon dioxide film.

On the first insulating film 7, a second insulating film 8 is formed as a liner insulating film. The second insulating film 8 is formed, for example, of a silicon dioxide film. The second insulating film 8 is formed to extend over and thus cover the gaps between the respective gates MG, between the gates MG and dummy gates DGD, and between the dummy gates DGD and the selector gates SGD. In addition, a spacer insulating film 9 is formed along the side of the selector gates SGD opposite to the gap and thus along the same side surfaces of the insulating films 2 to 8. The spacer insulating film 9 is formed, for example, of a silicon dioxide film.

A third insulating film 10 is formed on the second insulating film 8 and along an upper surface and a side surface (an outer surface) of the spacer insulating film 9. The third insulating film 10 is formed, for example, by a silicon dioxide film as a liner insulating film. On the third insulating film 10, a fourth insulating film 11 is formed. The fourth insulating film 11 is formed, for example, of a silicon nitride film.

On the fourth insulating film 11, an interlayer insulating film 12 is formed. The interlayer insulating film 12 is formed, for example, of silicon oxide. In the interlayer insulating film 12, a through hole is extended up to an upper surface of the semiconductor substrate 1, and the bit line contact electrode CB is embedded in the through hole.

On the bit line contact electrode CB, a conductive film 13 is formed. A contact electrode V1 is formed on the conductive film 13, and the bit line BL is formed on the contact electrode V1. The bit line BL is formed, for example, of a metal such as copper (Cu) as a main material. Furthermore, an upper layer wiring is further formed on the bit line BL, but it is not illustrated.

In addition, in a surface layer of the semiconductor substrate 1 between the respective gates MG, a dopant diffusion region 1a is formed which extends inwardly of the surface of the substrate 1. The dopant diffusion region 1a is, for example, a region in which n-type dopant is diffused at a low concentration. In addition, the dopant diffusion region 1a is also shallowly formed in the substrate 1 on the drain side of the selector gate SGD, and a highly-concentrated dopant diffusion region 1b is deeply formed into the substrate 1 starting at the side of the spacer insulating film 9 opposite to the selector gate SGD. The bit line contact electrode CB is formed to come in contact with an upper surface of the dopant diffusion region 1b. As shown in FIG. 3b, a shallow dopant diffusion region 1a extends into the substrate directly below the spacer insulating film 9 and up to the spacer insulating film 9 side of the selector gate SGD.

After such a structure is formed on a semiconductor wafer, the semiconductor wafer is cut by dicing to be the semiconductor chip 102. Subsequently, the semiconductor chip 102 is packaged (a mounting procedure). In the mounting procedure, a wire bonding procedure is included, and the package substrate 101 and the semiconductor chip 102 are electrically connected together by the bonding wire 103. Here, the wire bonding procedure includes a heating treatment (a reflow treatment) to cause solder to reflow and interconnect with the ends of the bonding wire and/or bonding pads.

Although not wishing to be bound by theory, the inventor believes that when a high temperature (for example, a temperature at which a solder is melted to reflow, that is, 170° C. to 180° C. or higher) is applied to the semiconductor chip 102 at the time of the reflow treatment with respect to the bonding wire 103 which is performed in the mounting procedure, as illustrated in FIG. 3B, for example, copper (Cu) which is a material of the bit line BL is mobilized (by ionization), and may move to the vicinity of the charge storage layer 3 of the memory cell MT.

That is, it is believed that copper (Cu) is ionized (Cu⁺ or Cu²⁺) into a mobile ion 50, and when it migrates into a memory cell MT, the performance of the memory cell is degraded, such as by lowering s the threshold voltage Vth of the memory cell MT, and thus the migration of the mobile ion 50 causes variations (a degradation) of the threshold voltages Vth of the memory cells MT.

Furthermore, it is estimated that in addition to the copper ion (Cu⁺), a different positive ion or the like such as a sodium ion (Na⁺), a potassium ion (K⁺), and a hydrogen ion (H⁺) may also be the mobile ion 50. The sodium ion (Na⁺), the potassium ion (K⁺), and the hydrogen ion (H⁺) are, in general, ions of chemical elements included in gases used in the manufacturing process of the device.

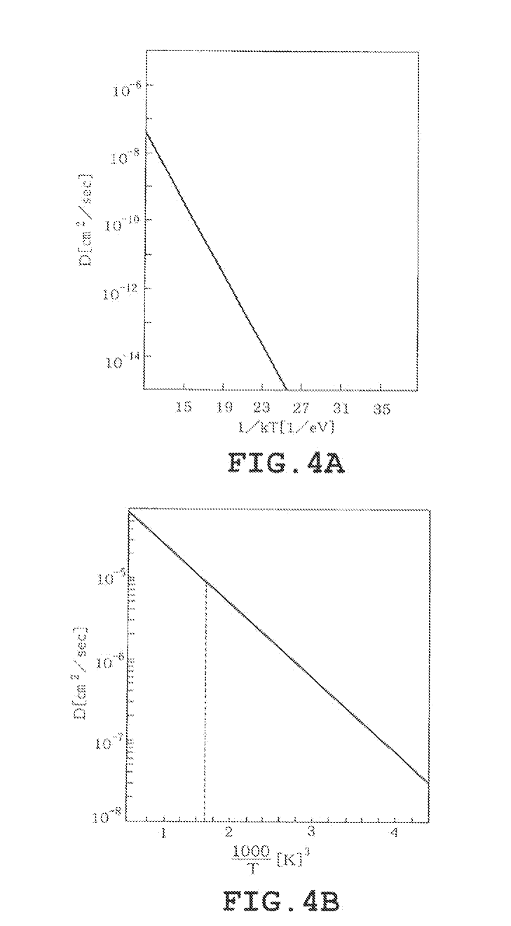

FIG. 4A illustrates the temperature relationship of the diffusion coefficient of copper in a silicon dioxide film. As illustrated in FIG. 4A, wherein the abscissa is 1 divided by the temperature in degrees Kelvin times the Boltzmann constant, when the temperature T decreases, the diffusion coefficient D=D0×exp^{(-Ea/kT)} decreases, and when the temperature T increases, the diffusion coefficient D increases. For example, the diffusion coefficient of a copper ion (cu⁺) in a silicon dioxide film, which is the material of the interlayer insulating film 12 is, for example, 1.0×10⁻¹⁴ [cm²/sec] at 180° C., and, for example, 5.0×10⁻¹⁹ [cm²/sec] at 80° C.

In addition, in this embodiment, a p-type silicon substrate is used as the semiconductor substrate 1. FIG. 4B illustrates the relationship of temperature to the diffusion coefficient of copper (Effective diffusion coefficient of Cu) in silicon into which boron (B) is doped as p-type dopant. As illustrated in FIG. 4B, when the temperature T decreases, the diffusion coefficient D decreases, and when the temperature T increases, the diffusion coefficient D increases. For example, the diffusion coefficient of a copper ion (cu⁺) in a silicon substrate doped with approximately 2×10¹⁵ [cm⁻²] of boron (B), is 1.0×10⁻⁶ to 1.0×10⁻⁵ [cm²/sec] at T=250° C. or 523° K (that is, 1,000/T≈1.91).

The mobile Cu ion 50 thus has a diffusion coefficient which is considerably high at a high temperature (for example, 170° C. to 180° C. or higher) environment even in silicon and even in a silicon dioxide film, compared to the diffusion thereof at room air temperature (a normal temperature). That is, in comparison with the temperature at the time of performing the reflow, the diffusion coefficient of the mobile ion is vanishingly small at a user operating temperature.

Here, a diffusion length of the mobile ion 50 will be described. The diffusion length indicates a diffusion distance that the mobile ion 50 may move at the time of being exposed to a specific temperature environment. It is assumed that a diffusion medium of the mobile ion 50 is a silicon dioxide film (SiO₂), and the threshold voltage is within the distribution “C” (refer to FIG. 1D: corresponding to an electric potential of the charge storage layer 3≈−2V), and heat is applied, for example, to maintain the device at 250° C. for 30 minutes during the reflow treatment. In this case, the diffusion coefficient of the copper ion in the silicon dioxide film is estimated as D=1.0×10⁻¹³ [cm²/sec], where T=250° C.

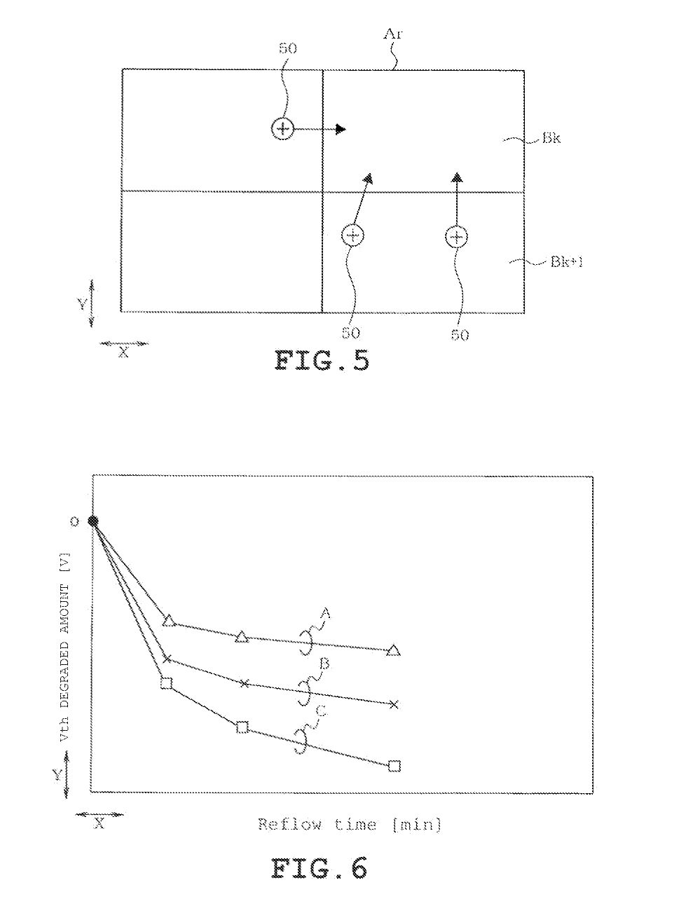

When a maximum electric field generated by the charge storage layer 3 at about 2V is E=˜0.07 [MV/cm], and a heating time is 30 minutes, ion mobility can be calculated as μ=e·D/(k·T)=1.48 [nm/sec], and a maximum velocity can be calculated as v=μ·E=1.48 [nm/sec]. When the charge storage layer 3 continuously outputs the maximum electric field, and the mobile ion 50 is moved at the maximum velocity v and for approximately 30 minutes, the movement distance is 2.7 [μm]. The distance is, for example, a distance in which movement of mobile ions 50 between adjacent blocks Bₖ-Bₖ₊₁ also may be caused as illustrated in FIG. 5. In such a case, performing the reflow treatment for approximately 30 minutes causes the movement of the mobile ions 50 between the blocks Bₖ−Bₖ₊₁ even in an electric field weaker than that described above.

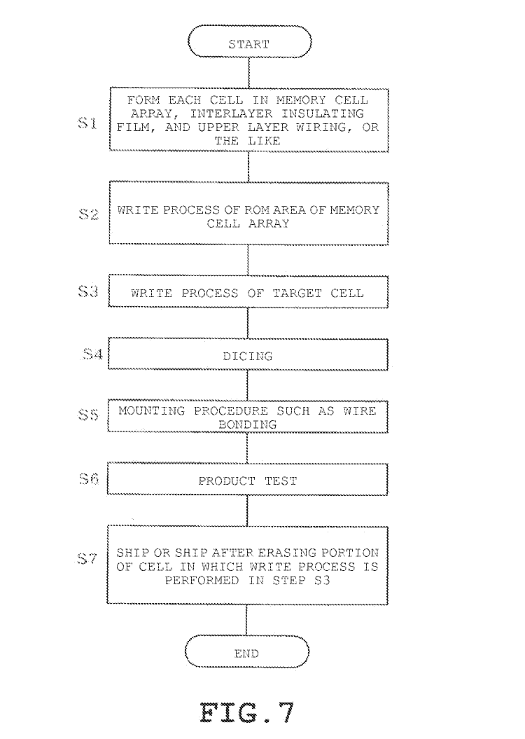

FIG. 6 illustrates the results of an experiment performed by the inventors, and an example of annealing time dependency on a threshold voltage degraded amount of the memory cell MT. As illustrated in FIG. 6, the threshold voltage Vth is considerably degraded as the reflow treatment time during wire bonding in increased.

A characteristic A in FIG. 6 indicates a characteristic of a threshold voltage Vth1 (a neutral threshold voltage) of the memory cell MT set at a relatively low threshold voltage distribution “A” (refer to FIG. 1D) during reflow. A characteristic B in FIG. 6 indicates a characteristic of a threshold voltage Vth2 (>the threshold voltage Vth1) of the memory cell MT set at an approximately middle threshold voltage distribution “B” (refer to FIG. 1D) during reflow. A characteristic C indicates a characteristic of a threshold voltage Vth3 (>the threshold voltage Vth2) of the memory cell MT set at a relatively high threshold voltage distribution “C” (refer to FIG. 1D) during reflow. The threshold voltage Vth of the memory cell MT is determined mainly by a charge amount accumulated in the charge storage layer 3. As the charge amount increases, the threshold voltage Vth increases, on the contrary, as the charge amount decreases, the threshold voltage Vth decreases.

As illustrated in FIG. 6, when the memory cell MT is set at the relatively high threshold voltage Vth3, performing the reflow treatment causes the threshold voltage Vth to be most critically degraded. That is, it is estimated that when a large number of electrons are accumulated in the charge storage layer 3 of the memory cell MT, the memory cell MT tends to attract a mobile copper ion (cu⁺) (which is a positive ion), and thus the threshold voltage Vth of the memory cell is considerably degraded.

Therefore, in this embodiment, the steps illustrated in FIG. 7 are performed. Furthermore, only the steps related to the present application are described, but other steps may be included between the steps, and the steps described below may be replaced with each other, as required.

As illustrated in FIG. 7, on the semiconductor substrate 1 (the semiconductor wafer), each cell (the memory cell MT, the dummy cells DTS and DTD, and the like) of the memory cell array Ar, the interlayer insulating film 12, and the upper layer wiring (the bit line BL and the like) are formed (Step S1).

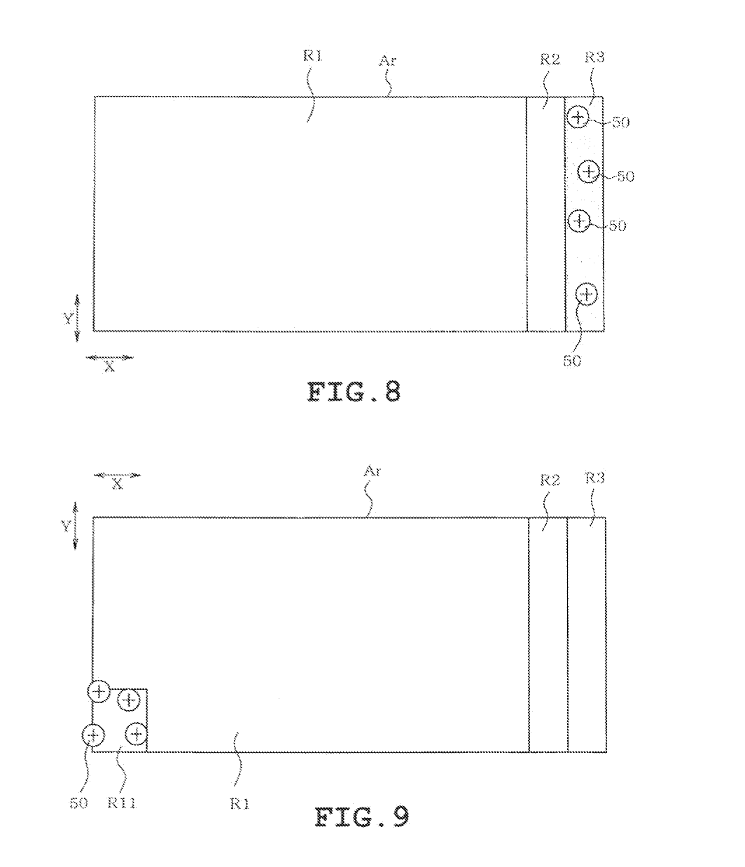

Then, the test apparatus Ta is connected to the memory cell device MD, and the control circuit CC performs the write process of information required for an operation of the semiconductor memory device MD in the ROM area R2 of the memory cell array Ar under command of the test apparatus Ta (Step S2). Furthermore, Step S2 may be performed during a die-sort procedure. Subsequently, the control circuit CC performs the write process to a “target cell” in the memory cell array Ar (Step S3), and thus a threshold voltage of the “target cell” is set to a second threshold voltage. In this embodiment, the “target cell” indicates, for example, the memory cell MT of the cell unit UC in the dummy area R3 illustrated in FIG. 8. The first threshold voltage is that voltage which is present irradiating the memory cell MT with ultraviolet, and the second threshold voltage is higher than the first threshold voltage. In addition, in Step S3, the memory cell MT of the user area R1 may be in an erased state (the threshold voltage is lower than or equal to the first threshold voltage).

Then, the individual semiconductor chip 102 is cut out from the semiconductor substrate 1 (the semiconductor wafer) (dicing: Step S4). Then, the semiconductor chip 102 is mounted on the packaging substrate 101, the reflow treatment is performed, for example, at 170° C. to 180° C. or higher, and the bonding wire 103 is connected between the respective bonding pads 101a and 102a (Step S5).

Then, in the reflow treatment, the mobile ion 50 is preferentially attracted to the “target cell” of the dummy area R3 because of the greater residual voltage on the dummy cell. As a result after reflow, the concentration of the mobile ions 50 in the memory cell MT of the dummy area R3 or in the vicinity of the memory cell MT is higher than that of the other areas of the dummy area R3.

When the “target cell” (the dummy cell having the higher voltage) is not disposed in the dummy area R3, the mobile ion 50 will move to the ROM area R2, and the information written in the ROM area R2 may be changed by the resulting variation of the threshold voltage of the memory cell MT as a result of the presence of the mobile ion 50. Accordingly, by performing the process of Step S3, it is possible to prevent the information written in the ROM area R2 from being changed during the reflow process of packaging.

Subsequently, a product test of the manufactured semiconductor memory device MD is performed by using the test apparatus Ta (Step S6). The semiconductor memory device MD which passes the product test is shipped (Step S7). At this time, the control circuit CC may apply an erase voltage to the “target cell” in which the write process was performed in Step S3 to erase the write data, and then the semiconductor memory device MD may be shipped (Step S7). At this time, the threshold voltage of the “target cell” decreases from the written second threshold voltage, and becomes a third threshold voltage.

The semiconductor memory device MD is used by the user mainly in a normal temperature (for example, tens of degrees centigrade) environment after being shipped, and it is highly unlikely the semiconductor memory device MD will be exposed to the solder melt temperature while being used by the user. According to the inventors, it is ascertained that when the mobile ion 50 is once attracted to the “target cell”, and an environmental temperature returns to, for example, the normal temperature, the mobile ion 50 is less likely to again diffuse elsewhere in the memory array Ar. Since the diffusion coefficient of the mobile ion 50 at the normal temperature is extremely small, the distance that the mobile ion 50 is diffused from within the “target cell” is minimal. In this point, it is possible to consider that the mobile ion 50 is captured in the “target cell”. Here, even when a write operation and an erase operation are performed in the memory cells MT of the user area R1, the mobile ion 50 barely moves in the direction of the user area R1 from the “target cell”.

Therefore, in the manufacturing steps before shipping, the mobile ion 50 is captured in one or more “target cells”, and thus, subsequently, it is possible to prohibit the threshold voltage Vth of the memory cell MT from being degraded by further diffusion of the mobile ion 50 even when, for example, the user uses the semiconductor memory device MD at the normal temperature.

Furthermore, if the threshold voltage Vth of the memory cells MT is adjusted to a threshold voltage (a so-called neutral threshold: for example, the vicinity of the threshold voltage distribution “A” of FIG. 1D) after erasing any charge thereon by application of ultraviolet electromagnetic energy, the mobile ion 50 will still remain in the target cell when heat of a solder melt temperature range (for example, at 170° C. to 180° C. or higher) is applied. In Step S3, by setting the memory cells MT of the user region R1 to the erased state, the memory cell MT of the area R1 does not have an effect of attracting the positively charged mobile ion 50. As a result, it is possible to easily capture the mobile ion (s) 50 in one or more target cells in the dummy area R3.

In addition, in this embodiment, by disposing the “target cell” in the dummy area R3, it is possible to prevent the information written in the ROM area R2 from being changed. In addition, since the mobility of the mobile ion 50 is small at normal operating temperatures, it is possible to store data in the dummy area R3. For example, it is possible to use the dummy area R3 as a temporal memory region, or as a redundancy region.

In addition, when the bonding wire 103 is formed by copper (Cu), or when copper (Cu) is included in the solder for adhering the bonding wire 103, or the like, the effect of copper which is effused from the bonding wire 103 or the solder at the time of adhering the bonding wire 103 to the semiconductor chip 102, is also considered. In such a case, by disposing the dummy area R3 at the bonding location of the wire, it is possible to suppress the detrimental effect of copper ions effused from the bonding wire 103 into the memory cell array Ar.

### Modification Example

As illustrated in FIG. 1A, FIG. 3A, and FIG. 3B, dummy cells DTD are disposed between the selector transistors STD and the memory cells MT in order to preferably maintain the write, the erase, and the read characteristics of the memory cells MT.

In the first embodiment, a cell in the dummy area R3 is the target cell, but the dummy cell DTD may be used as the “target cell” and thus the target cell which captures the mobile ion is within the blocks of the memory array Ar. That is, in Step S3 of FIG. 7, the control circuit CC may write the threshold voltage Vth of one or more of the dummy cells DTD to a threshold voltage which is higher than the neutral threshold voltage at the time of erasing the charge on the memory cells MT by ultraviolet exposure. Then, the mobile ion 50 is easily attracted to the dummy cell(s) DTD, and thus it is possible to reduce the effect of the degradation of the threshold voltage Vth of the memory cells MT.

The memory cell array Ar is configured with the cell units UC extending substantially over the entire region thereof, and the threshold voltage of the dummy cells DTD and DTS of the cell units UC in the entire region may be set to be high, or the threshold voltage of a portion of the dummy cells DTD and DTS may be set to be high.

### Second Embodiment

FIGS. 8 and 9 illustrate a second embodiment. In the second embodiment, the “target cell” is disposed in an ECC region R11. The ECC region R11 is a region in which an error correction code is stored. In the ECC region R11, similar to the user area R1, cell units UC are formed. The ECC region R11 may be disposed within a portion of the memory cell array Ar.

That is, in Step S3 of FIG. 7, according to the command from the external test apparatus Ta, the control circuit CC writes the memory cell MT of the cell unit UC of the ECC region R11 to a threshold voltage which exceeds the neutral threshold voltage. Subsequently, when performing the solder reflow procedure to bond the bonding wire 103 to bond pads, the semiconductor chip 102 is exposed to a high temperature environment. At this time, the mobile ion 50s are attracted to the target cell(s) in the ECC region R11. Accordingly, it is possible to capture the mobile ions 50 in one or more target cells of the ECC region R11. Accordingly, the mobile ions will be captured in the target cells, and the information subsequently written in the ROM area R2 will not be changed due to the influence of mobile ions 50.

Subsequently, even when the semiconductor memory device MD is used at the normal temperature, the mobile ion 50 captured in the ECC region R11 is less likely to be further diffused. That is, in normal temperature operations, a movement amount of the mobile ions 50 is small, and thus the memory cells MT of the ECC region have a small variation in a threshold value. For this reason, the ECC region R11 may be used as a region in which the error correct code is stored.

### Third Embodiment

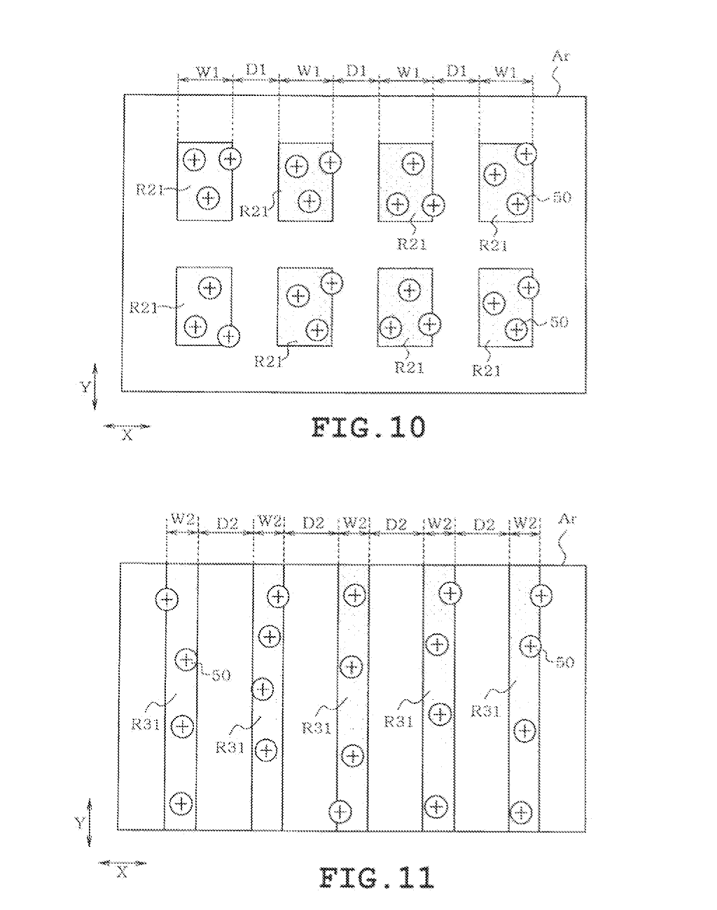

FIG. 10 and FIG. 11 illustrate a third embodiment. In the third embodiment, a plurality of dummy areas are provided in the memory cell array Ar, and the distance D1 between the adjacent dummy areas R21 disposed in the memory cell array Ar spaced apart at an interval equal to an assumed diffusion length of the mobile ions 50, or at an interval narrower than the diffusion length.

As illustrated in FIG. 10, the dummy areas R21 in the memory cell array Ar are rectangular when viewed from above. A plurality of dummy areas R21 are separately disposed in the X direction and in the Y direction.

The width of the adjacent dummy areas R21 in the X direction is set to a width W1, and the distance between adjacent dummy areas R21 in the X direction is set to a distance D1. The distance D1 between the adjacent dummy areas R21 may be set at an interval equal to the diffusion length (for example, 2.7 [μm]) of the mobile ion 50 when the memory device is exposed to 170° C. to 180° C. or higher and for a predetermined period of time (for example, 30 minutes) during the solder reflow process, or at an interval less than the diffusion length.

Even when one or more mobile ions 50 are present in the memory cell array Ar before the reflow treatment, the mobile ion (s) 50 in substantially the entire memory cell array Ar may be captured in the target cells of the dummy area R21 during the reflow procedure. As a result, the concentration of the mobile ions 50 in the array is periodic, i.e., the concentration is high in the dummy areas R21, and low to none in the regions of the memory cell array Ar therebetween.

Subsequently, even when the semiconductor memory device MD is used at normal operating temperatures, the mobile ion 50 captured in the dummy area R31 is less likely to be diffused. In addition, the dummy area R31 may be used as a region in which user data is stored.

In addition, the dummy areas R31 illustrated in FIG. 10 may extend in an extended region which planarly extends in a predetermined direction, for example the dummy areas R31 may be linearly disposed across the entire memory cell array Ar Y direction as shown in FIG. 11. The distance D2 between the adjacent dummy areas R31 may be set at an interval equal to twice the diffusion length of the mobile ion 50 at the time of being exposed to 170° C. to 180° C. or higher and for a predetermined period of time (for example, 30 minutes) during the solder reflow step of packaging, or at an interval narrower than twice the diffusion length.

Even when the mobile ion 50 is present in the memory cell array Ar before the reflow treatment, the mobile ions 50 in substantially the entire memory cell array Ar may be captured in the target cell (s) of the dummy area R31 at the time of performing the reflow procedure. The resulting concentration of the mobile ions 50 is periodic in the X direction in the memory cell array Ar.

As a result, it is possible to obtain the same effect as the first and the second embodiments. In addition, subsequently, even when the semiconductor memory device MD is used at normal operating temperatures, the mobile ion 50 captured in the dummy area R31 is unlikely to be further diffused. In addition, the dummy area R31 is also able to be used as the region in which the user data is stored.

### Fourth Embodiment

In a fourth embodiment, the “target cell” is disposed in the ROM area R2. For example, the ROM area R2 is operated by a Multi Level Cell (MLC) at the time of capturing the mobile ion 50.

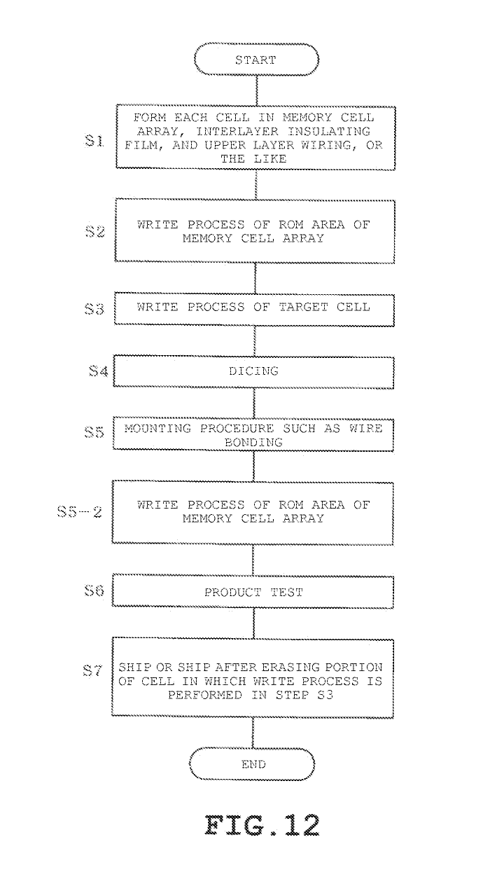

That is, after Step S2 of FIG. 12, in Step S3, the control circuit CC writes the memory cells MT of the cell units UC of the ROM area R2 to a threshold voltage (for example, within the threshold voltage distribution “B” or “C” (refer to FIG. 4B)) which exceeds the neutral threshold voltage, according to the command from the external test apparatus Ta.

Subsequently, by performing the connecting procedure of the bonding wires 103, the semiconductor chip 102 is exposed to a high temperature environment. During this procedure, it is possible to attract the mobile ions 50 to the target cell or cells in the ROM area R2. Accordingly, it is possible to capture the mobile ion(s) 50 in the target cell or cells of the ROM area R2.

Subsequently, the test apparatus Ta sets the threshold voltage of the memory cell MT in the ROM area R2 to the erased state, and then writes a parameter required for an operation of the semiconductor memory device MD in the memory cells MT of the ROM area R2 (Step S5-2). Subsequently, the product test is performed (Step S6), and the semiconductor memory device MD is shipped (Step S7). As a result, it is possible to keep the information written in the ROM area R2 from being changed.

Furthermore, the ROM area R2 is an area in which the information is stored in a nonvolatile way in the normal temperature environment, and when the target cell (s) of the ROM area R2 once capture the mobile ion (s) 50, the captured mobile ion (s) 50 is less likely to be diffused to the other cells. For this reason, the ROM area R2 may be used as a region in which information is stored. In addition, by configuring the memory cells MT of the ROM area R2 the same as the memory cells MT of the SLC, the required data maintenance characteristic is more relaxed than that of the memory cell MT of the MLC. As a result, even when the target cell is disposed in the ROM area R2, an effect on the operation of the semiconductor memory device MD is small.

### Other Embodiments

The present invention is not limited to the embodiments described above, and may be modified or expanded, for example, as the following. Although the dummy area R3 according to the first embodiment is disposed in the end portion of the memory cell array Ar, it is not limited thereto. The dummy area R3 may be freely disposed in the memory cell array Ar, and in this case, a freedom degree such as the width or size of the dummy area, and the location of the dummy areas, is increased.

Although the memory cell array Ar in which the memory cells MT are disposed in a 2-dimensional planar direction (an XY direction) is described, the invention may also be applied to a nonvolatile semiconductor memory device provided with a cell array in which a plurality of memory cells MT are disposed in a 3-dimensional direction (an XYZ direction). By suitably selecting some configurations among all of the configurations described above, it is possible to freely control the captured amount of the mobile ion 50.

While certain embodiments have been described, these embodiments have been presented by way of example only, and are not intended to limit the scope of the inventions.

Indeed, the novel devices and methods described herein may be embodied in a variety of other forms; furthermore, various omissions, substitutions and changes in the form of the embodiments described herein may be made without departing from the spirit of the inventions.

The accompanying claims and their equivalents are intended to cover such forms or modifications as would fall within the scope and spirit of the inventions.

What is claimed is:

1. A semiconductor memory device manufacturing method for mounting a semiconductor chip in which memory cells are provided on a packaging substrate, the method comprising: selecting a target cell from among the memory cells in the memory device;
setting the voltage of the memory cells to a first voltage and the voltage of the target cell to a second voltage, greater than the first voltage;
performing wire bonding to attach wires between the semiconductor chip and the packaging substrate at a first temperature which is higher than a normal operating temperature of the semiconductor memory device after the voltage of the target cell is set to the second voltage; and
setting the second voltage of the target cell to a third voltage which is lower than the second voltage by reducing the second voltage after the semiconductor chip is wire bonded to the packaging substrate.

2. The semiconductor memory device manufacturing method of claim 1, further comprising:
before setting the voltage of the memory cells and target cell, exposing the memory cells and target cell to ultraviolet energy.

3. The semiconductor memory device manufacturing method of claim 1, wherein the first temperature is a solder reflow temperature.

4. The semiconductor memory device manufacturing method of claim 1, further comprising:
selecting a second target cell in a location spaced from the target cell, and applying the second voltage to the second target cell before exposing the semiconductor chip and the packaging substrate to the first temperature.

5. A semiconductor memory device, comprising:
a semiconductor chip that includes a memory area including first memory regions and second memory regions for storing data provided within a memory cell; and
a packaging substrate including a bonding wire which is bonded to the semiconductor chip by wire bonding at a first time and temperature,
wherein a concentration of a chemical element of a mobile ion in the first memory region is higher than a concentration of a chemical element of a mobile ion in the second memory region.

6. The semiconductor memory device according to claim 5,
wherein the first memory regions and the second memory regions are periodically disposed across the memory area.

7. The semiconductor memory device according to claim 6,
wherein the spacing between the first memory regions is equal to or less than the distance that the mobile ion may diffuse in the semiconductor chip at the first time and temperature.

8. The semiconductor memory device according to claim 7,
wherein the first temperature greater than or equal to 180° C.

9. The semiconductor memory device according to claim 5,
wherein the semiconductor chip further comprises a bonding pad to which the bonding wire is attached.

10. The semiconductor memory device according to claim 5,
wherein the bonding wire comprises copper.

11. The semiconductor memory device according to claim 5,
wherein the chemical element of the mobile ion comprises copper, sodium, potassium, or hydrogen.

12. The semiconductor memory device according to claim 5,
wherein the first memory region includes one or more dummy cells therein.

13. The semiconductor memory device according to claim 5,
wherein the first memory region is an ECC region.

14. The semiconductor memory device according to claim 5,
wherein the first memory region is a ROM region.

15. The semiconductor memory device according to claim 14,
wherein a memory cell of an SLC is disposed in the ROM region.

16. The semiconductor memory device according to claim 5,
wherein the first memory region is rectangular.

17. The semiconductor memory device according to claim 5,
wherein the first memory region is disposed at an end portion of the semiconductor chip.

18. The semiconductor memory device according to claim 5,
wherein the mobile ion is a hydroxide ion (OH⁻), or an oxonium ion (H₃O⁺).

19. A semiconductor device wherein a mobile ion having a detrimental effect on cell performance is captured, comprising:
a cell region comprising a plurality of active cells and at least one target cell, wherein the mobile ion is captured in the target cell.

20. The semiconductor device according to claim 19, where the cell region further comprises a plurality of unit cells, and each unit cell includes opposed selector cells, a plurality of memory cells disposed between the selector cells, and at least one dummy cell located between a selector cell and a memory cell.
